(19) United States
(12) Patent Application Publication
(10) Pub. No.: US 2007/0148349 A1
(43) Pub. Date: Jun. 28, 2007

(54) SHOWERHEAD, FILM FORMING APPARATUS INCLUDING SHOWERHEAD AND METHOD FOR MANUFACTURING FERROELECTRIC FILM

(75) Inventor: Shinichi FUKADA, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/615,315

(22) Filed: Dec. 22, 2006

(30) Foreign Application Priority Data
Dec. 27, 2005 (JP) 2005-374502

(51) Int. Cl. C23C 16/00; H01L 21/20

(52) U.S. Cl. 427/248.1; 118/715; 438/584

(57) ABSTRACT

A showerhead used for forming a ferroelectric film includes: a first gas chamber that is charged with a first gas including at least a metal element composing the ferroelectric film; a second gas chamber that is charged with at least a second gas that reacts with the first gas; a first nozzle connected to the first gas chamber; and a second nozzle connected to the second gas chamber, wherein the first nozzle is equipped with a first discharge nozzle that discharges the first gas, the second nozzle is equipped with a second discharge nozzle that discharges the second gas, and the first discharge nozzle protrudes greater than the second discharge nozzle.

The entire disclosure of Japanese Patent Application No. 2005-374502, filed Dec. 27, 2005 is expressly incorporated by reference herein.

### BACKGROUND

1. Technical Field

The invention relates to showerheads, film forming apparatuses including showerheads, and methods for manufacturing ferroelectric films.

2. Related Art

Ferroelectric memory devices (FeRAM) are nonvolatile memories that are capable of low voltage and high-speed operations, and their memory cell can be formed from one transistor and one capacitor (1T/1C), such that integration to the level of DRAM is possible. Accordingly, ferroelectric memory devices are highly expected as large-capacity nonvolatile memories.

As a film forming method for forming ferroelectric films composing a ferroelectric memory, a physical vapor deposition (PVD) method, such as, an electron beam deposition method, a sputter method and a laser aberration method; a chemical solution deposition (CSD) method; a chemical vapor phase deposition method; and a metal organic chemical vapor deposition (MOCVD) method may be enumerated. Above all, for manufacturing a ferroelectric memory device having a stacked structure in which a ferroelectric capacitor is provided on a plug conductive layer, which has been developed in recent years, a MOCVD method may be suitably used. This is because, according to the MOCVD method, layers with controlled crystal orientation can be readily deposited, under processing conditions in which the processing temperature and other conditions are restricted so as not to affect elements such as transistors provided in underlying layers.

Japanese laid-open patent applications JP-A-2002-30445 and JP-A-2001-262352 describe showerhead structures used with a MOCVD apparatus. The showerheads described in these documents have a structure with a plurality of divided and isolated gas diffusion chambers, wherein material gases are discharged from the respective gas diffusion chambers into a reaction chamber (reaction containers).

When the film forming apparatus having the showerhead described in the above documents JP-A-2002-30445 and JP-A-2001-262352 is used to form ferroelectric films, gases as metal sources, and reaction gases for reacting (oxidizing or reducing) with these metal sources are discharged into the chamber through individual nozzles. At this time, when a substrate is heated, the surface of the showerhead opposing to the substrate surface may also be heated, and films may also be formed on the showerhead surface. This may result in particles, which would affect the film quality of the ferroelectric film.

### SUMMARY

In accordance with an advantage of some aspects of the present invention, it is possible to provide a showerhead and a film forming apparatus which are suitable for forming films with good film quality, without particles being contained. It is also possible to provide a film forming method for forming ferroelectric films which uses the aforementioned film forming apparatus.

(1) A showerhead in accordance with a first embodiment of the invention pertains to a showerhead used for forming a ferroelectric film, the showerhead including:

a first gas chamber that is charged with a first gas including at least a metal element composing the ferroelectric film;

a second gas chamber that is charged with at least a second gas that reacts with the first gas;

a first nozzle connected to the first gas chamber; and

a second nozzle connected to the second gas chamber,

wherein the first nozzle is equipped with a first discharge nozzle that discharges the first gas, the second nozzle is equipped with a second discharge nozzle that discharges the second gas, and the first discharge nozzle protrudes greater than the second discharge nozzle.

In the first showerhead in accordance with the embodiment described above, the first discharge nozzle is provided at a position closer to an object to be processed, compared to the second discharge nozzle. For this reason, the first gas containing a metal source that is to be supplied through the first discharge nozzle can be securely supplied to the surface of the object to be processed. When the first gas containing a metal source is pushed back towards the discharge surface side, the first gas may be decomposed adjacent to the discharge surface that is heated by radiant heat, and an unintended film may be deposited on the discharge surface. However, according to the embodiment, the first gas can be supplied from a position that is close to the surface of the object to be processed, such that an unintended film composed of the material of the first gas is prevented from being deposited on the discharge surface. As a result, sources of particles can be reduced, and a ferroelectric film with improved film quality can be formed.

(2) A showerhead in accordance with a second embodiment of the invention pertains to a showerhead used for forming a film, the showerhead including:

a first gas chamber that is charged with a first gas;

a second gas chamber that is charged with a second gas;

a first nozzle connected to the first gas chamber; and

a second nozzle connected to the second gas chamber,

wherein the first nozzle is equipped with a first discharge nozzle that discharges the first gas, and at least a portion of an inner wall of the second nozzle has a shape that is directed toward the first discharge nozzle.

According to the second showerhead in accordance with the second embodiment of the invention, the second nozzle may have an inversely tapered shape. For this reason, the second gas is supplied while radially expanding along the slope of the side surface of the inverse tapered section. Such a flow of the second gas contributes to directing the second gas flow toward the surface of the object to be processed. For example, depending on the kind of the first gas, when the first gas is pushed back toward the discharge surface side, the first gas may be decomposed adjacent to the discharge surface that is heated by radiant heat, and an unintended film may be deposited on the discharge surface. However, according to the embodiment, such a problem can be prevented. As a result, generation of particles can be suppressed, and a designed film with good film quality can be formed. In the showerhead in accordance with the present embodiment, the “inversely tapered shape” means a shape in which a nozzle aperture becomes greater toward a location where the object to be processed is disposed.

The showerhead in accordance with the embodiment of the invention may be formed with any of the following modes.

(3) In the showerhead in accordance with an aspect of the embodiment of the invention, the second nozzle may have a first portion located on the side of the second gas chamber and a second portion located on the side where the second gas is discharged, and the second portion may have an inversely tapered shape.

(4) In the showerhead in accordance with an aspect of the embodiment of the invention, a side surface of the inversely tapered shape may be a curved surface.

(5) In the showerhead in accordance with an aspect of the embodiment of the invention, the second nozzle may be equipped with a second discharge nozzle that discharges the second gas, wherein a portion of the first discharge nozzle and a portion of the second discharge nozzle contact each other.

(6) In the showerhead in accordance with an aspect of the embodiment of the invention, the showerhead may be used for forming a ferroelectric film, wherein the first gas may contain at least a metal element composing the ferroelectric film, and the second gas includes a gas that reacts with the first gas.

(7) A film forming apparatus in accordance with an embodiment of the invention pertains to a film forming apparatus for depositing a predetermined film, and includes a processing container, and any one of the showerheads described above in accordance with the embodiment of the invention.

By the film forming apparatus in accordance with the embodiment described above, deposition of an unintended film on the discharge surface can be suppressed, and a film forming apparatus with reduced generation of particles can be provided.

(8) A method for manufacturing a ferroelectric film in accordance with an embodiment of the invention is conducted with the film forming apparatus in accordance with the embodiment of the invention described above. According to the method for manufacturing a ferroelectric film in accordance with the embodiment of the invention, a ferroelectric film can be manufactured with the film forming apparatus in which generation of particles is suppressed, such that a ferroelectric film with good film quality and excellent crystal orientation can be manufactured.

### BRIEF DESCRIPTION OF THE DRAWINGS

FIG. 1 is a schematic view of a film forming apparatus in accordance with a first embodiment of the invention.

FIG. 2 is an enlarged view of a showerhead included in the apparatus shown in FIG. 1.

FIG. 3 is a schematic view of a showerhead of a film forming apparatus in accordance with a second embodiment of the invention.

FIG. 4 is a schematic view of a showerhead of a film forming apparatus in accordance with a third embodiment of the invention.

FIG. 5 is a cross-sectional view for describing a step of a method for manufacturing a ferroelectric capacitor in accordance with an embodiment of the invention.

FIG. 6 is a cross-sectional view for describing a step of the method for manufacturing a ferroelectric capacitor in accordance with the embodiment of the invention.

### 1. FILM FORMING APPARATUS

### 1.1. First Embodiment

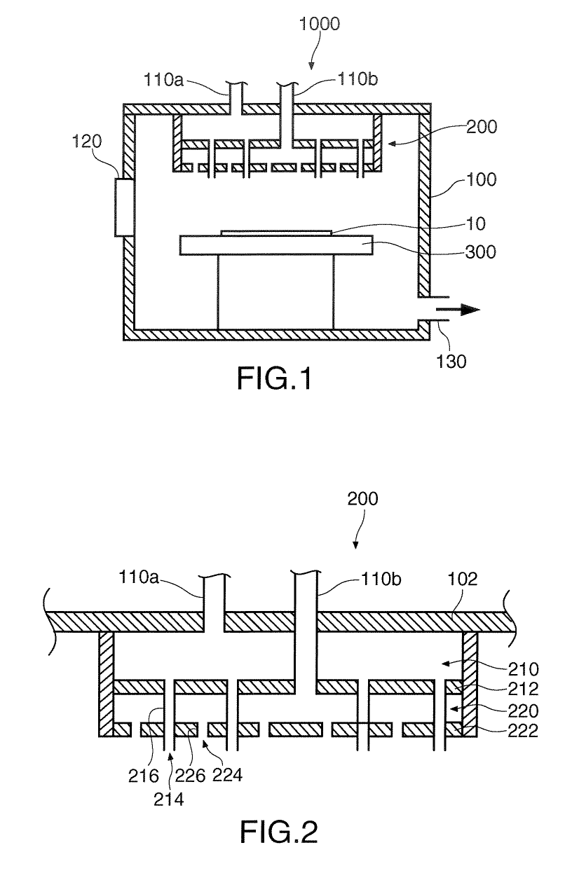

An example of a film forming apparatus in accordance with an embodiment of the invention is described with reference to the accompanying drawings. FIG. 1 is a schematic diagram of a film forming apparatus 1000 in accordance with the present embodiment. FIG. 2 is an enlarged view of a showerhead 200 included in the film forming apparatus 1000 in accordance with the embodiment.

As shown in FIG. 1, the film forming apparatus in accordance with the present embodiment has an aluminum processing container 100 having an internal cavity space. A showerhead 200 that is a gas supply system for supplying gases required for film forming, and a support base 300 for disposing an object to be process 10 (a base substrate on which films are formed) are provided inside the processing container 100. The processing container 100 is provided at least with gas introduction ports 110a and 110b for introducing gases required for film formation, a transfer entrance 120 for transferring a member to be processed inside the processing container 100, and an exhaust port 130 for pressure-reducing or exhausting gases from the processing container 100. The transfer port 120 may be equipped with a gate valve (not shown) for opening and closing the transfer port 120 in an air-tight manner. Also, the exhaust port 130 may be provided with a known exhaust system, such as, an exhaust pipe, a vacuum pump (not shown) and the like. Furthermore, the exhaust system may be provided with a valve for adjusting the pressure inside the processing container 100.

The support base 300 may have a resistance heater formed from kanthal or the like, or a heating device formed from a lamp heater or the like (not shown). Also, the supporting base 300 may be provided with a transfer mechanism (not shown) that is capable of movements in up and down directions, such that the distance between the support base 300 and the showerhead 200 can be adjusted.

Next, the showerhead device 200 included in the film forming apparatus 100 in accordance with the present embodiment is described in detail with reference to FIG. 2.

As shown in FIG. 2, the showerhead 200 is attached to a lower surface of a top sheathing 102 of the processing container 100. The shower head 200 may have a cylindrical shape with a bottom. The top sheathing 102 may be attached to the cylindrical body portion through a sealing member (not shown) such as an o-ring or the like, to maintain air-tightness of the processing chamber 100. The showerhead 200 may be entirely formed from, for example, nickel, nickel alloy, aluminum, or aluminum alloy.

A first gas chamber 210 for diffusing first gas and a second gas chamber 220 for diffusing second gas are provided in the showerhead 200 in a manner that they are divided and separated from one another. The showerhead 200 in accordance with the present embodiment is provided with a partition plate 212 disposed in a horizontal direction to divide and separate vertically the first gas chamber 210 and the second gas chamber 220 from each other.

The first gas chamber 210 is connected to the gas introduction port 110a provided on the processing container 100. The second gas chamber 220 is similarly connected to the second gas introduction port 110b provided on the processing container 100. It is noted that the second gas introduction port 110b penetrates the first gas chamber 210.

A bottom plate (hereafter also referred to as a “discharge surface”) 222 of the showerhead 200 is provided with nozzles for supplying first and second gases inside the processing container 100. More concretely, first nozzles 216 for supplying the first gas and second nozzles 226 for supplying the second gas are provided. The first nozzles 216 penetrate the second gas chamber 220. The first nozzles 216 and the second nozzles 226 may be disposed in plurality generally uniformly in a plane in a matrix configuration. The first nozzles 216 have first discharge ports 214 at one end sections thereof oriented in a direction in which the first gas is discharged. The second nozzles 226 have second discharge ports 224 at one end sections thereof oriented in a direction in which the second gas is discharged.

Further referring to FIG. 2, the positional relation between the first discharge ports 214 and the second discharge ports 224 is described. As shown in FIG. 2, in accordance with the present embodiment, the first discharge ports 214 are provided at a position protruded from the discharge surface 222. In other words, the first discharge ports 214 and the second discharge ports 224 make the positions where the different gases are discharged into the processing space different from each other. By this, the first gas can be supplied at a position closer to the surface of a substrate to be processed 10, compared to the second gas.

The film forming apparatus in accordance with the present embodiment can be used for forming a ferroelectric film. Gas containing a metal source can be used as the first gas, and gas that reacts with (oxidizes or reduces) the metal source can be used as the second gas.

In the film forming apparatus in accordance with the first embodiment, the first discharge ports 214 are provided at a shorter distance to the substrate to be processed 10, compared with the second discharge ports 224, in the showerhead 200. Therefore, a metal source gas (the first gas) that is supplied through the first discharge ports 214 can be securely supplied to the surface of the substrate to be processed. Accordingly, deposition of a film composed of the metal source gas as raw material on the discharge surface 222 can be suppressed. As a result, generation sources of particles can be reduced, and a ferroelectric film with improved film quality can be formed.

### 1.2. Second Embodiment

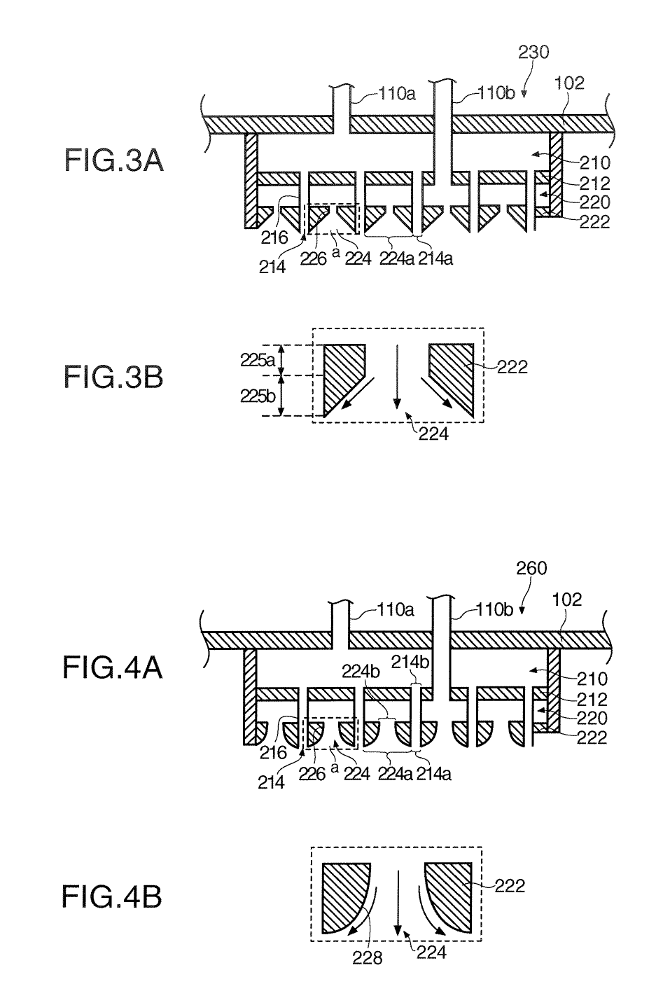

Next, a film forming apparatus in accordance with a second embodiment is described with reference to FIGS. 3A and 3B. FIG. 3A is a view for describing a showerhead 230 in accordance with the second embodiment, and shows a portion corresponding to FIG. 2. FIG. 3B is an enlarged view of a portion a indicated in FIG. 3A. It is noted that the film forming apparatus in accordance with the second embodiment is an example in which the shape of second discharge ports 224 provided in a discharge surface 222 is different from the first embodiment. The structure of a film forming apparatus 1000 of the second embodiment is generally the same as that of the first embodiment, and therefore its detailed description is omitted.

As shown in FIG. 3A, in the film forming apparatus in accordance with the second embodiment, a portion of the second nozzle 226 has an inversely tapered shape with respect to the gas discharge direction (indicated by an arrow). By this, the second discharge port 224a has a larger plane configuration, than the plane configuration of the first discharge port 214a. Also, as shown in FIG. 3B, the second nozzle 226 has a first portion 225a on the side of the second gas chamber, and a second portion 225b on the side of the discharge surface. In the present embodiment, the second portion 225b alone has an inversely tapered shape.

In the film forming apparatus in accordance with the second embodiment, the showerhead 230 has the second nozzles 226 in an inversely tapered shape. For this reason, the second gas is supplied while radially expanding along an inclination in the inversely tapered shape. Also, the first discharge port 214 is provided on an extended line of the inclination, such that the first gas moves together with the flow of the second gas toward the surface of the member to be processed. In other words, the second gas contributes to directing the first gas toward the surface of the member to be processed. As a result, like the first embodiment, deposition of an unintended film on the discharge surface can be suppressed, and generation of particles can be suppressed, such that a designed film with good film quality can be formed.

Moreover, as the inversely tapered shape is provided in the second nozzle 226, the surface area of the discharge surface 222 can be increased. This feature can suppress an elevation in the temperature of the discharge surface 222 of the showerhead 230 due to radiant heat caused by heating of the member to be processed. As a result, deposition of an unintended film can be better suppressed.

It is noted that the second embodiment exemplifies a case in which the second portion 225b of the second nozzle alone has an inversely tapered shape. However, the present invention is not limited to this shape. For example, the second nozzle 226 may have an inversely tapered shape as a whole.

### 1.3. Third Embodiment

Next, a film forming apparatus in accordance with a third embodiment is described with reference to FIGS. 4A and 4B. FIG. 4A is a view for describing a showerhead 260 in accordance with the third embodiment, and shows a portion corresponding to FIG. 2. FIG. 4B is an enlarged view of a portion a indicated in FIG. 4A. It is noted that the film forming apparatus in accordance with the third embodiment is an example in which the shape of second discharge ports 224 provided in a discharge surface 222 is different from the first embodiment. The structure of a film forming apparatus 1000 of the second embodiment is generally the same as that of the first embodiment, and therefore its detailed description is omitted.

As shown in FIG. 4A, in the film forming apparatus in accordance with the third embodiment, the other end 214b of the first nozzle 216 (on the side where the first nozzle 216 connects to the first gas chamber 210) and the other end 224b of the second nozzle 224 have different sizes. Further, in the second nozzle 226, the discharge port 224a has a greater plane configuration, compared to the other end 224b, which form a so-called inversely tapered shape.

As shown in FIG. 4B, the second nozzle 226 has a side surface 228 with an inversely tapered shape, which has a curved surface that protrudes towards the center of the second discharge port 224a. In other words, the side surface 228 has a curved surface that bulges toward the flow direction of the second gas.

In the film forming apparatus in accordance with the third embodiment, the showerhead 260 is provided with the second nozzles 226 each having an inversely tapered shape, and having a curved surface protruding toward the center of the second nozzle 226. For this reason, the flow of the second gas can be made smoother. As a result, the film forming apparatus in accordance with the third embodiment has actions similar to those of the film forming apparatus of the second embodiment, generation of particles can be suppressed, and a designed film with good film quality can be formed. Also, because the second nozzles 226 have curved surfaces, the surface area can be further increased, compared to the film forming apparatus in accordance with the second embodiment. By this, an elevation in the temperature of the discharge surface can be better suppressed, and formation of an unintended film can be suppressed.

2. Film Forming Method for Forming Ferroelectric Film

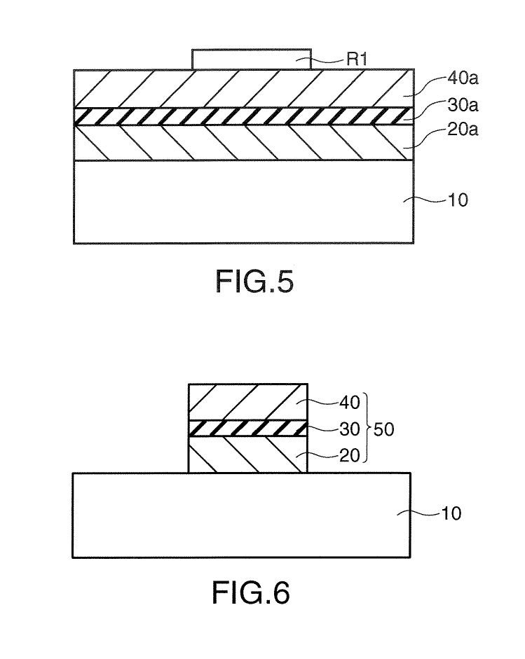

Next, a method for forming a ferroelectric film which uses the film forming apparatus described above is described with reference to FIG. 5 and FIG. 6. In the description of the film forming method, an example for forming a ferroelectric capacitor having electrodes provided above and below a ferroelectric film is described. FIG. 5 and FIG. 6 are cross-sectional views schematically showing steps of the method for manufacturing a ferroelectric capacitor.

As shown in FIG. 5, first, a base substrate 10 is prepared. As the base substrate 10, for example, a semiconductor substrate can be used. Then, on the base substrate 10, a first electrode 20a is formed by, for example, a sputter method. The material of the first electrode 20a may be composed of at least one kind of metals selected from platinum, ruthenium, rhodium, palladium, osmium and iridium. The first electrode 20a may preferably be composed of platinum or iridium, and more preferably, iridium. Also, the first electrode 20a may be in a single film or a multilayer film of laminated layers.

Then, a ferroelectric film 30a is formed on the first electrode 20a. The ferroelectric film 30a is formed by using the film forming apparatus 1000 described above. In this case, organometallic materials may be dissolved in solution, and gas that is obtained by vaporizing the solution may be used as the first gas. As the organometallic materials, for example, a solution of Ti (s−Am)₂ (DMHD)₂ (titanium (secondary aluminum alkoxide) (dimethyl heptanedionate)), or Ti (iPrO)₂ (DPM)₂ (titanium (isoproxy) (dipivaloyl methanate)) dissolved in a predetermined ratio in tetrahydroflan (THF) may be used as the Ti source. Also, a solution of Zr (DMHD)₄ (zirconium (dimethyl heptanedionate)) or Zr (DPM)₄ (zirconium (dipivaloyl methanate)) dissolved in a predetermined ratio in THF may be used as the Zr source. Further, a solution of, for example, Pb(DPM)₂ (lead (dipivaloyl methanate)) dissolved in a predetermined ratio in THF may be used as the Pb source. These solutions are vaporized, and can be introduced together with a carrier gas into the processing container 100. As the carrier gas, an inert gas such as N₂ gas, Ar gas or the like can be used.

As the second gas, oxygen gas may be used. Also, by appropriately adjusting the heater system provided at the support base 300, the substrate temperature is adjusted between 500° C. and 650° C. This temperature range is a temperature range in which crystalline ferroelectric layers can be formed, and is applicable when PZT is used as the materials.

Then, a second electrode 40a is formed on the ferroelectric film 30a. The second electrode 40a may be formed by a method similar to the method applied for forming the first electrode 20a. A mask layer M1 is formed on a laminated body 10 composed of the first electrode 20a, the ferroelectric film 30a and the second electrode 40a. For example, a resist layer can be used as the mask layer R1.

Then, as shown in FIG. 6, exposed portions of the laminated body 10 are removed. The removal of the laminated body 10 may be conducted by a known etching technique. Also, after the patterning step, heat treatment for recovering crystallinity may be conducted if necessary. By the process described above, the ferroelectric capacitor 50 can be manufactured.

According to the method for manufacturing a ferroelectric film in accordance with the embodiment described above, the ferroelectric film 30 with improved crystal orientation and excellent quality can be formed. The film forming apparatus 1000 used in the present embodiment suppresses generation of particles. In order to improve the characteristics of the ferroelectric capacitor 50, the crystal orientation of the ferroelectric film 30 is important. If particles are mixed during the film forming process, crystal growth may take place with the particles being as cores, and a film having random crystal orientation may be formed. However, according to the method for manufacturing a ferroelectric film in accordance with the present embodiment, the aforementioned problems are suppressed, and ferroelectric films with improved crystal orientation can be manufactured.

It is noted that the invention is not limited to the embodiments described above, and many modifications can be made. For example, the invention may include compositions that are substantially the same as the compositions described in the embodiments (for example, a composition with the same function, method and result, or a composition with the same objects and result). Also, the invention includes compositions in which portions not essential in the compositions described in the embodiments are replaced with others. Also, the invention includes compositions that achieve the same functions and effects or achieve the same objects of those of the compositions described in the embodiments. Furthermore, the invention includes compositions that include publicly known technology added to the compositions described in the embodiments.

What is claimed is:

1. A showerhead used for forming a ferroelectric film, the showerhead comprising:
a first gas chamber that is charged with a first gas including at least a metal element composing the ferroelectric film;
a second gas chamber that is charged with at least a second gas that reacts with the first gas;
a first nozzle connected to the first gas chamber; and
a second nozzle connected to the second gas chamber,
wherein the first nozzle is equipped with a first discharge nozzle that discharges the first gas, the second nozzle is equipped with a second discharge nozzle that discharges the second gas, and the first discharge nozzle protrudes greater than the second discharge nozzle.

2. A showerhead used for forming a film, the showerhead comprising:
a first gas chamber that is charged with a first gas;
a second gas chamber that is charged with a second gas;
a first nozzle connected to the first gas chamber; and
a second nozzle connected to the second gas chamber,
wherein the first nozzle is equipped with a first discharge nozzle that discharges the first gas, and at least a portion of an inner wall of the second nozzle has a shape that is directed toward the first discharge nozzle.

3. A showerhead according to claim 2, wherein the second nozzle has a first portion located on a side of the second gas chamber and a second portion located on a side where the second gas is discharged, and the second portion has an inversely tapered shape.

4. A showerhead according to claim 2, wherein a side surface of the inversely tapered shape is a curved surface.

5. A showerhead according to claim 2, wherein the second nozzle is equipped with a second discharge nozzle that discharges the second gas, and a portion of the first discharge nozzle and a portion of the second discharge nozzle contact each other.

6. A showerhead according to claim 2, wherein the showerhead is used for forming a ferroelectric film, wherein the first gas contains at least a metal element composing the ferroelectric film, and the second gas includes a gas that reacts with the first gas.

7. A film forming apparatus for depositing a predetermined film, the film forming apparatus comprising:
a processing container; and
the showerhead recited in claim 1 provided in the processing container.

8. A method for manufacturing a ferroelectric film formed with the film forming apparatus recited in claim 7.
